(19) United States
(12) Patent Application Publication
(10) Pub. No.: US 2024/0339403 A1
(43) Pub. Date: Oct. 10, 2024

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Moorym Choi, Suwon-si (KR); Taeyong Kim, Suwon-si (KR); Sunil Shim, Suwon-si (KR); Minhee Lee, Suwon-si (KR); Yunsun Jang, Suwon-si (KR); Hayoung Jeong, Suwon-si (KR)

(21) Appl. No.: 18/405,362

(22) Filed: Jan. 5, 2024

(30) Foreign Application Priority Data
Apr. 4, 2023 (KR) 10-2023-0043992

(51) Int. Cl. H01L 23/528; H01L 23/522; H01L 25/065; H10B 41/10; H10B 41/27; H10B 41/35; H10B 43/10; H10B 43/27; H10B 43/35; H10B 80/00

(52) U.S. Cl. CPC H01L 23/5283; H01L 23/5226; H01L 25/0652; H10B 41/10; H10B 41/27; H10B 41/35; H10B 43/10; H10B 43/27; H10B 43/35; H10B 80/00; H01L 2225/06506

(57) ABSTRACT

A semiconductor device includes a first semiconductor structure including a first substrate, and a lower bonding structure on the first substrate, and a second semiconductor structure including a second substrate, and an upper bonding structure bonded to the lower bonding structure. The second semiconductor structure includes via patterns on the second substrate, a source contact pad including a material different from that of the second substrate, a source contact plug electrically connected to the source contact pad, a source contact via on the source contact pad, and an interconnection line that electrically connects the via patterns to the source contact plug. Lower surfaces of the via patterns are farther from the first substrate than a lower surface of the source contact via, and an upper surface of the second substrate is farther from the first substrate than an upper surface of the source contact pad.

### CROSS-REFERENCE TO RELATED APPLICATION(S)

This application claims the benefit of priority to Korean Patent Application No. 10-2023-0043992 filed on Apr. 4, 2023 in the Korean Intellectual Property Office, the disclosure of which is incorporated herein by reference in its entirety.

### BACKGROUND

Example embodiments of the present disclosure relate to a semiconductor device and a data storage system including the same.

In data storage systems requiring data storage, semiconductor devices capable of storing high-capacity data are in demand. Accordingly, a method for increasing data storage capacity of a semiconductor device is being researched. For example, as a method for increasing data storage capacity of a semiconductor device, a semiconductor device including three-dimensionally arranged memory cells, instead of two-dimensionally arranged memory cells, has been proposed.

### SUMMARY

Example embodiments of the present disclosure provide a semiconductor device having improved electrical properties and reliability.

Example embodiments of the present disclosure provide a data storage system including a semiconductor device having improved electrical properties and reliability.

According to example embodiments of the present disclosure, a semiconductor device includes a first semiconductor structure including a first substrate, circuit devices on the first substrate, a lower interconnection structure electrically connected to the circuit devices, and a lower bonding structure electrically connected to the lower interconnection structure, and a second semiconductor structure including a second substrate on the first semiconductor structure, gate electrodes stacked and spaced apart from each other in a vertical direction perpendicular to a lower surface of the second substrate, channel structures that penetrate the gate electrodes, extend in the vertical direction, and each of the channel structures including a respective channel layer, an upper interconnection structure between the gate electrodes and the lower interconnection structure, and an upper bonding structure electrically connected to the upper interconnection structure and bonded to the lower bonding structure. The second semiconductor structure includes via patterns on the second substrate, a source contact pad spaced apart from the second substrate in a direction parallel to the lower surface of the second substrate and including a material different from that of the second substrate, a source contact plug electrically connected to the source contact pad and between the source contact pad and the lower interconnection structure, a source contact via on the source contact pad, and an interconnection line in contact with an upper surface of each of the via patterns on the second substrate, in contact with an upper surface of the source contact via, and electrically connecting the via patterns and the source contact plug to each other. At least a portion of lower surfaces of each of the via patterns is farther from the first substrate than a lower surface of the source contact via, and wherein at least a portion of an upper surface of the second substrate is on a level higher than a level of an upper surface of the source contact pad.

According to example embodiments of the present disclosure, a semiconductor device includes a first substrate, circuit devices on the first substrate, a lower interconnection structure electrically connected to the circuit devices, a lower bonding structure electrically connected to the lower interconnection structure, an upper bonding structure bonded to the lower bonding structure, an upper interconnection structure electrically connected to the upper bonding structure; a second substrate on the upper interconnection structure, gate electrodes between the upper interconnection structure and the second substrate, stacked and spaced apart from each other in a vertical direction perpendicular to a lower surface of the second substrate, channel structures that penetrate the gate electrodes and each of the channel structures includes a channel layer, via patterns on the second substrate, a source contact plug spaced apart from the gate electrodes in a direction parallel to the lower surface of the second substrate on an external side of the second substrate and having an upper surface that is farther from the first substrate than a a lower surface of the second substrate, a source contact via electrically connected to the source contact plug on the source contact plug, and an interconnection line in contact with an upper surface of each of the via patterns on the second substrate and in contact with an upper surface of the source contact via on an external side of the second substrate. A lower surface of the source contact via is farther from the first substrate than at least a portion of an upper surface of the second substrate. The channel layer protrudes into the second substrate.

According to example embodiments of the present disclosure, a data storage system includes a semiconductor storage device including a first semiconductor structure including a first substrate with circuit devices on the first substrate, a second semiconductor structure including a second substrate, gate electrodes stacked and spaced apart from each other between the second substrate and the first substrate, and channel structures that penetrate the gate electrodes, and an input/output pad electrically connected to the circuit devices, and a controller electrically connected to the semiconductor storage device through the input/output pad and configured to control the semiconductor storage device. The first semiconductor structure includes a lower interconnection structure electrically connected to the circuit devices, and a lower bonding structure electrically connected to the lower interconnection structure. The second semiconductor structure includes an upper bonding structure bonded to the lower bonding structure, an upper interconnection structure connected to the upper bonding structure, via patterns on the second substrate, a source contact pad spaced apart from the second substrate in a direction parallel to the lower surface of the second substrate and including a material different from a material of the second substrate, a source contact plug electrically connected to the source contact pad and between the source contact pad and the first substrate, a source contact via electrically connected to the source contact plug; and an interconnection line in contact with upper surfaces of the via patterns on the second substrate, in contact with an upper surface of the source contact via on an external side of the second substrate, and electrically connect the via patterns to the source contact plug. At least a portion of the lower surfaces of each of the via patterns is farther from the first substrate than a lower surface of the source contact via. At least a portion of an upper surface of the second substrate is farther from the first substrate than an upper surface of the source contact pad.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is an exploded perspective diagram illustrating a semiconductor device according to example embodiments of the present disclosure;

FIG. 2A is a plan diagram illustrating a portion of components of a semiconductor device according to example embodiments of the present disclosure;

FIG. 2B is a cross-sectional diagram illustrating a semiconductor device according to example embodiments of the present disclosure;

FIG. 2C is an enlarged cross-sectional diagram illustrating a portion of a semiconductor device according to example embodiments of the present disclosure;

FIGS. 3A, 3B, 4, 5A and 5B are enlarged cross-sectional diagrams illustrating a portion of a semiconductor device according to example embodiments of the present disclosure;

FIG. 6 is a cross-sectional diagram illustrating a semiconductor device according to example embodiments of the present disclosure;

FIGS. 7A and 7B are plan diagrams illustrating a portion of a semiconductor device according to example embodiments of the present disclosure;

FIGS. 8A, 8B, 8C, 8D, 8E, 8F, 8G and 8H are cross-sectional diagrams illustrating a method of manufacturing a semiconductor device according to example embodiments of the present disclosure;

FIG. 9 is a diagram illustrating a data storage system including a semiconductor device according to example embodiments of the present disclosure;

FIG. 10 is a perspective diagram illustrating a data storage system including a semiconductor device according to example embodiments of the present disclosure; and

FIG. 11 is a cross-sectional diagram illustrating a semiconductor package according to example embodiments of the present disclosure.

### DETAILED DESCRIPTION

Hereinafter, embodiments of the present disclosure will be described as follows with reference to the accompanying drawings.

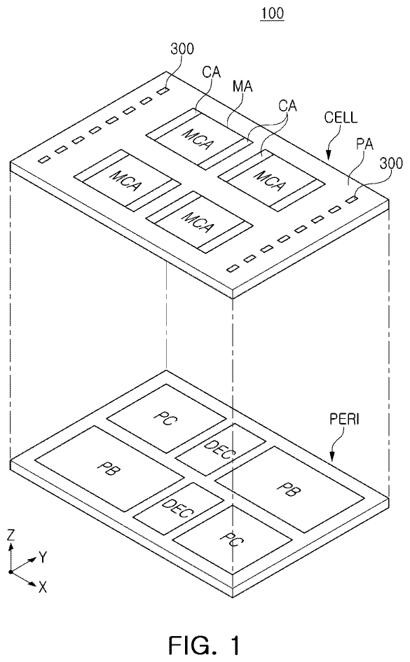

FIG. 1 is an exploded perspective diagram illustrating a semiconductor device according to example embodiments.

Referring to FIG. 1, a semiconductor device 100 according to example embodiments may include a peripheral circuit region PERI and a memory cell region CELL stacked in a vertical direction Z. The peripheral circuit region PERI and the memory cell region CELL may be bonded to each other. The memory cell region CELL may include a memory cell array region MCA, connection regions CA adjacent to the memory cell array region MCA, and an external region PA disposed on an external side thereof. A conductive pad 300, which is an input/output pad, may be disposed on the external region PA. A plurality of memory cell structures including the memory cell array region MCA and the connection region CA may be disposed.

The peripheral circuit region PERI may include a raw decoder DEC, a page buffer PB and another peripheral circuit PC. In the peripheral circuit region PERI, the raw decoder DEC may generate drive signals of a word line by decoding an input address and may transmit the signals. The page buffer PB may be connected to the memory cell array region MCA through bit lines and may read data stored in the memory cells. The other peripheral circuit PC may be a region including control logic and a voltage generator, and may include, for example, a latch circuit, a cache circuit, and/or a sense amplifier. The peripheral circuit region PERI may further include another pad region, and in this case, the pad region may include an electrostatic discharge ESD device or a data input/output circuit. The ESD device or a data input/output circuit of the pad region may be electrically connected to the conductive pad 300 of the external region PA. Various circuit regions DEC in the peripheral circuit region PERI, PB, and PC may be disposed in various forms.

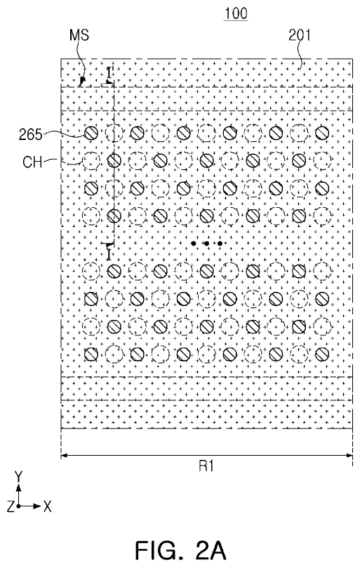

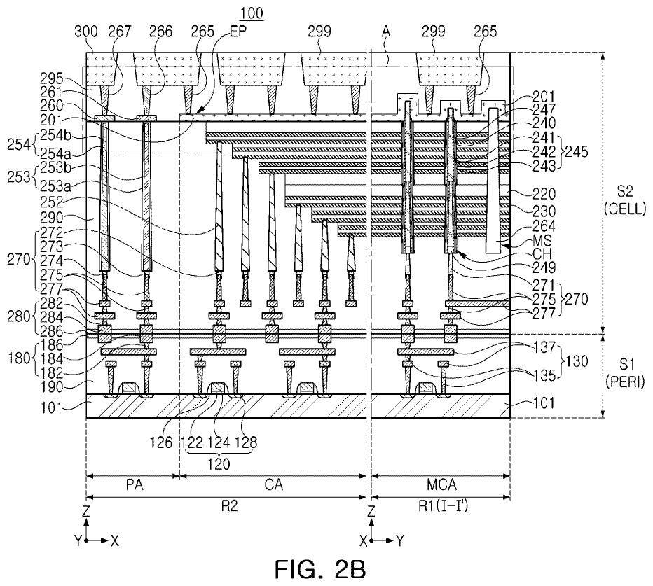

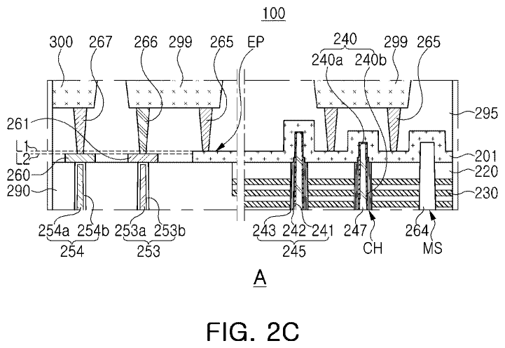

Hereinafter, an example of the semiconductor device 100 will be described with reference to FIGS. 2A to 2C. In FIGS. 2A and 2B, a first region R1 may be configured as the memory cell array region MCA illustrated in FIG. 1, and a second region R2 may be configured as the connection region CA and the external region PA illustrated in FIG. 1. In FIGS. 2A and 2B, the region indicated by the first region R1 may represent a cross-sectional shape obtained by cutting a portion of the memory cell array region MCA illustrated in FIG. 1 in the Y-direction in the semiconductor device 100, and the region indicated by the second region R2 may represent a cross-sectional shape obtained by cutting a portion of the connection region CA and the external region PA illustrated in FIG. 1 in the X-direction in the semiconductor device 100.

FIG. 2A is a plan diagram illustrating a portion of components of a semiconductor device according to example embodiments. FIG. 2B is a cross-sectional diagram illustrating a semiconductor device according to example embodiments. FIG. 2C is an enlarged cross-sectional diagram illustrating a portion of a semiconductor device according to example embodiments. FIG. 2A illustrates shapes and an arrangement relationship between a second substrate 201 including a common source line, via patterns 265, channel structures CH, and isolation regions MS to indicate a positional relationship between via patterns 265 and channel structures CH. The region denoted as a first region R1 in FIG. 2B indicates a cross-section taken along line I-I′ in FIG. 2A. FIG. 2C is an enlarged diagram illustrating region “A” in FIG. 2B.

Referring to FIGS. 2A, 2B and 2C, a semiconductor device 100 may include a peripheral circuit region PERI and a memory cell region CELL. The memory cell region CELL may be disposed on the peripheral circuit region PERI. The peripheral circuit region PERI and the memory cell region CELL may be bonded to each other through bonding structures 180 and 280. The peripheral circuit region PERI may be referred to as a first semiconductor structure S1, and the memory cell region CELL may be referred to as a second semiconductor structure S2.

The peripheral circuit region PERI may include a first substrate 101, circuit devices 120 on the first substrate 101, a lower interconnection structure 130, a lower bonding structure 180, and a lower capping layer 190.

The first substrate 101 may include a semiconductor material, for example, a group IV semiconductor, a group III-V compound semiconductor, or a group II-VI compound semiconductor. The first substrate 101 may be provided as a bulk wafer or epitaxial layer. In the first substrate 101, an active region may be defined by device isolation layers. Source/drain regions 128 including impurities may be disposed in a portion of the active region.

The circuit devices 120 may include transistors. Each of the circuit devices 120 may include a circuit gate dielectric layer 122, a circuit gate electrode 124, and a source/drain region 128. The source/drain regions 128 including impurities may be disposed in the first substrate 101 on both sides of the circuit gate electrode 124. Spacer layers 126 may be disposed on both sides of the circuit gate electrode 124. The circuit gate dielectric layer 122 may include silicon oxide, silicon nitride, or a high-k material. The circuit gate electrode 124 may include at least one of titanium nitride (TiN), tantalum nitride (TaN), and tungsten nitride (WN), titanium silicon nitride (TiSiN), tantalum silicon nitride (TaSiN), and tungsten silicon nitride (WSiN), tungsten (W), copper (Cu), aluminum (Al), molybdenum (Mo), and/or ruthenium (Ru). The circuit gate electrode 124 may include a semiconductor layer, for example a doped polycrystalline silicon layer. In example embodiments, the circuit gate electrode 124 may include two or more multiple layers.

The lower interconnection structure 130 may be electrically connected to the circuit gate electrodes 124 and the source/drain regions 128 of the circuit devices 120. The lower interconnection structure 130 may include lower contact plugs 135 in the shape of a cylinder or truncated cone and lower interconnection lines 137 in which at least one region has a line shape. A portion of the lower contact plugs 135 may be connected to the source/drain regions 128, and although not illustrated, the other portion of the lower contact plugs 135 may be connected to the gate electrodes 124. The lower contact plugs 135 may electrically connect the lower interconnection lines 137 disposed on different levels from an upper surface of the first substrate 101. The lower interconnection structure 130 may include a conductive material, for example, tungsten (W), copper (Cu), aluminum (Al), and the like, and each component may further include a diffusion barrier comprising at least one of titanium (Ti), titanium nitride (TiN), tantalum (Ta), tantalum nitride (TaN), and/or tungsten nitride (WN). In example embodiments, the number of layers of the lower contact plugs 135 and the lower interconnection lines 137 included in the lower interconnection structure 130 and arrangement form thereof may be varied.

The lower bonding structure 180 may be connected to the lower interconnection structure 130. The lower bonding structure 180 may include a lower bonding via 182, a lower bonding pad 184, and a lower bonding insulating layer 186. The lower bonding via 182 may be connected to the lower interconnection structure 130. The lower bonding pad 184 may be connected to the lower bonding via 182. The lower bonding via 182 and lower bonding pad 184 may include a conductive material, for example, tungsten (W), copper (Cu), aluminum (Al), and/or the like, and each component may further include a diffusion barrier. The lower bonding insulating layer 186 may also function as a diffusion barrier of the lower bonding pad 184 and may include at least one of SiCN, SiO, SiN, SiOC, SiON and/or SiOCN. The lower bonding insulating layer 186 may have a thickness less than that of the lower bonding pad 184, but an example embodiment thereof is not limited thereto. The lower bonding structure 180 may be bonded or connected to each other by being in direct contact with the upper bonding structure 280 by hybrid bonding. For example, the lower bonding pad 184 may be in contact with the upper bonding pad 284 and may be bonded to each other by copper-to-copper bonding, and the lower bonding insulating layer 186 may be in contact with the upper bonding insulating layer 286 and may be bonded to each other by dielectric-to-dielectric bonding. The lower bonding structure 180 may provide an electrical connection path between the peripheral circuit region PERI and the memory cell region CELL along with the upper bonding structure 280.

The lower capping layer 190 may be disposed on the first substrate 101 and may cover or overlap the circuit devices 120 and the lower interconnection structure 130. The lower capping layer 190 may include a plurality of insulating layers. The lower capping layer 190 may include an insulating material such as silicon oxide, silicon nitride, silicon oxynitride, or silicon oxycarbide.

The memory cell region CELL may include a second substrate 201, gate electrodes 230 stacked below the second substrate 201, isolation region MS extending by penetrating through a stack structure of the gate electrodes 230, channel structures CH disposed to penetrate the stack structure, contact plugs 252, 253, and 254 for electrical connection with the peripheral circuit region PERI, an upper interconnection structure 270 below the stack structure, and an upper bonding structure 280 connected to the upper interconnection structure 270.

The memory cell region CELL may further include interlayer insulating layers 220 alternately stacked with gate electrodes 230 below the second substrate 201, via patterns 265 on the second substrate 201, a source contact via 266 on a source contact plug 253 among the contact plugs 252, 253, and 254, a peripheral contact via 267 on the peripheral contact plug 254, a source contact pad 261 between the source contact via 266 and the source contact plug 253, a peripheral contact pad 260 between the peripheral contact via 267 and the peripheral contact plug 254, an upper capping layer covering or overlapping the stack structure, an upper insulating layer 295 on the second substrate 201 and in contact with an external side end of the second substrate 201, an interconnection line 299 on the via patterns 265 and the source contact via 266, and a conductive pad 300 on the peripheral contact via 267.

The memory cell region CELL may be defined by a first region R1 corresponding to a memory cell array region MCA, and a second region R2 corresponding to a connection region CA and an external region PA.

As illustrated in FIG. 2B, in the first region R1, gate electrodes 230 may be stacked and spaced apart from each other in a vertical direction, for example, in the Z-direction, and channel structures CH may be disposed such that they intersect the gate electrodes 230. As illustrated in FIG. 2B, in the second region R2, gate electrodes 230 may extend to different lengths such that contact pads for electrically connecting the memory cells to the peripheral circuit region PERI may be provided. Also, the second region R2 may further include a region from an external side end of the second substrate 201 to an edge of the semiconductor device 100. For example, the second region R2 may include a region in which the source contact pad 261, the peripheral contact pad 260, the source contact plug 253, the peripheral contact plug 254, and the conductive pad 300 are disposed. The first region R1 and the second region R2 may be understood as a region including the second substrate 201 and the region below and above the second substrate 201.

The second substrate 201 may include a semiconductor material, for example, a group IV semiconductor, a group III-V compound semiconductor, or a group II-VI compound semiconductor. For example, the group IV semiconductor may include silicon (Si), germanium (Ge) or silicon-germanium SiGe. The second substrate 201 may function as a common source line of the semiconductor device 100. For example, the second substrate 201 may include a doped polysilicon layer having an N-type conductivity. The second substrate 201 may also be referred to as a source layer, a source conductive layer, a semiconductor plate layer, or a plate layer. The channel layer 240 may be in contact with the second substrate 201. In example embodiments, the second substrate 201 may be formed to conformally cover or overlap the channel structures CH and the source contact plug 253, but example embodiments thereof are not limited thereto. For example, since the second substrate 201 may have a curved structure or a protruding portion, at least a portion of the upper surface of the second substrate 201 may be disposed on a level higher than a level of an upper surface of the source contact pad 261 with respect to the bottom surface of the second substrate 201.

The gate electrodes 230 may be vertically stacked and spaced apart from each other below the second substrate 201 and may form a stack structure. The gate electrodes 230 may be disposed between the second substrate 201 and the upper interconnection structure 270. The gate electrodes 230 may include electrodes forming a ground select transistor, memory cells, and a string select transistor in order from the second substrate 201. The number of gate electrodes 230 included in the memory cells may be determined depending on storage capacity of the semiconductor device 100. In example embodiments, the number of gate electrodes 230 included in the string select transistor and the ground select transistor may be one or two or more, and may have a structure the same as or different from the gate electrodes 230 of the memory cells. Also, the gate electrodes 230 may further include a gate electrode 230 disposed below the gate electrode 230 included in the string select transistor and above the gate electrode 230 included in the ground select transistor, and forming an erase transistor used for an erase operation using gate induced drain leakage (GIDL) phenomenon.

The gate electrodes 230 may be stacked and spaced apart from each other in the vertical direction in the memory cell array region MCA, may extend to different lengths from the memory cell array region MCA to the connection region CA and may form a staircase form step structure. As illustrated in FIG. 2C, the gate electrodes 230 may have a step structure in the X-direction and may be disposed to have a step structure in the Y-direction as well. By the step structure, the gate electrodes 230 may form a staircase form in which the upper gate electrode 230 may extend longer than the lower gate electrode 230, and may provide ends exposed from the interlayer insulating layers 220 toward the first substrate 101. In example embodiments, the gate electrodes 230 have an increased thickness on the ends.

The gate electrodes 230 may form a lower gate stack group and an upper gate stack group on the lower gate stack group. The interlayer insulating layer 220 disposed between the lower gate stack group and the upper gate stack group may have a relatively thick thickness, but example embodiments thereof are not limited thereto. In FIG. 2A, two stack groups of the gate electrodes 230 may be disposed vertically, but example embodiments thereof are not limited thereto, and the gate electrodes 230 may form a stack group or a plurality of stack groups.

The gate electrodes 230 may include a metal material, such as tungsten (W). In example embodiments, the gate electrodes 230 may include polycrystalline silicon or a metal silicide material. In example embodiments, the gate electrodes 230 may further include a diffusion barrier, and for example, the diffusion barrier may include tungsten nitride (WN), tantalum nitride (TaN), titanium nitride (TiN), or a combination thereof.

The gate electrodes 230 may be disposed such that at least a portion may be separated by a predetermined unit by the isolation regions MS in the Y-direction. Between a pair of isolation regions MS adjacent to each other, the gate electrodes 230 may form a memory block, but the example of the memory block is not limited thereto.

The interlayer insulating layers 220 may be disposed between the gate electrodes 230. Similarly to the gate electrodes 230, the interlayer insulating layers 220 may be spaced apart from each other in a direction perpendicular to a lower surface of the second substrate 201 and may extend in the X-direction. The interlayer insulating layers 220 may include an insulating material such as silicon oxide or silicon nitride.

The isolation region MS may be disposed to extend in the Z-direction through the gate electrodes 230 in the memory cell agrray region MCA and the connection region CA. The isolation region MS may penetrate through the isolation region MS and may be connected to the second substrate 201. The isolation insulating layer 264 may be disposed in the isolation regions MS. The isolation region MS may have a shape of which a width may decrease toward the second substrate 201 due to a high aspect ratio. The isolation region MS may extend in the X-direction and may isolate the gate electrodes 230 from each other in the Y-direction. In example embodiments, a conductive layer may be further disposed in the isolation insulating layer 264 in the isolation regions MS. The isolation insulating layer 264 may include an insulating material such as silicon oxide or silicon nitride, and may include, for example, silicon oxide, silicon nitride, or silicon oxynitride.

The channel structures CH may form a memory cell string, and may be spaced apart from each other while forming rows and columns in the memory cell array region MCA. The channel structures CH may be disposed to form a lattice pattern in the X-Y plane or may be disposed in a zigzag pattern in one direction. The channel structures CH may penetrate through the gate electrodes 230, may extend in a vertical direction perpendicular to the lower surface of the second substrate 201, for example, in the Z-direction, may have a columnar shape, and may have an inclined side surface of which a width may decrease toward the second substrate 201 depending on an aspect ratio.

Each of the channel structures CH may have a form in which lower and upper channel structures penetrating through the lower gate stack group and the upper gate stack group of the gate electrodes 230 are connected, respectively, and may have a bent portion due to a difference or a change in width in the connection region.

A channel layer 240 may be disposed in the channel structures CH. The channel layer 240 may be connected between the lower channel structure and the upper channel structure. The channel layer 240 may include a protrusion 240a and a non-protrusion 240b of the channel layer 240. The protruding lengths of the protrusions 240a in the channel structures CH may not be the same, but example embodiments thereof are not limited thereto. The protruding lengths of the protrusions 240a may be a distance of extension beyond a surface such as, for example, a top surface of interlayer insulating layers 220. In example embodiments, an upper surface of the second substrate 201 may have a curved structure or protruding structure on the channel layer 240. The channel layer 240 may be formed in an annular shape surrounding a channel buried insulating layer 247 disposed therein, but, in example embodiments, the channel layer 240 may have a columnar shape such as a cylinder or a prism without the channel buried insulating layer 247. The channel layer 240 may be in contact with the second substrate 201. For example, the protrusion 240a of the channel layer 240 may be connected to the second substrate 201 on the channel layer 240. An uppermost end of the channel layer 240 may be disposed on a level higher than a level of an uppermost end of the source contact plug 253. The channel layer 240 may include a semiconductor material such as polycrystalline silicon or single crystal silicon, and the semiconductor material may be an undoped material or a material including P-type or N-type impurities. In example embodiments, an uppermost end of the channel layer 240 may be in contact with the second substrate 201.

The channel pads 249 may be disposed below the channel layer 240 in the channel structures CH. The channel pads 249 may be disposed to cover or overlap a lower surface of the channel buried insulating layer 247 and to be electrically connected to the channel layer 240. The channel pads 249 may include, for example, doped polycrystalline silicon.

The channel dielectric layer 245 may be disposed between the gate electrodes 230 and the channel layer 240. The channel dielectric layer 245 may include a tunneling layer 241, a charge storage layer 242 and a blocking layer 243 stacked in order from the channel layer 240. The tunneling layer 241 may tunnel electric changes into the charge storage layer 242, and may include, for example, silicon oxide (SiO₂), silicon nitride (Si₃N₄), silicon oxynitride (SiON), or a combination thereof. The charge storage layer 242 may be a charge trap layer or a floating gate conductive layer. The blocking layer 243 may include silicon oxide (SiO₂), silicon nitride (Si₃N₄), silicon oxynitride (SiON), a high-k dielectric material, or a combination thereof. In example embodiments, at least a portion of the channel dielectric layer 245 may extend in a horizontal direction along the gate electrodes 230.

Each of the contact plugs 252, 253, and 254 may have a cylindrical shape or a truncated cone shape, and may have a width decreasing toward an upper portion depending on an aspect ratio. The contact plugs 252, 253, and 254 may penetrate through a portion of the upper capping layer 290. The contact plugs 252, 253, and 254 may include a gate contact plug 252, a source contact plug 253, and a peripheral contact plug 254. The gate contact plug 252, the source contact plug 253, and the peripheral contact plug 254 may be spaced apart from each other and a plurality of the gate contact plug 252, the source contact plug 253, and the peripheral contact plug 254 may be provided. Each of the contact plugs 252, 253, and 254 may include a conductive layer and a barrier layer surrounding side surfaces and one end of the conductive layer. For example, as illustrated in FIG. 2C, each of the contact plugs 253 and 254 may include conductive layers 253a and 254a and barrier layers 253b and 254b, and the barrier layers 253b and 254b may surround upper and side surfaces of the conductive layers 253a and 254a. The conductive layers 253a and 254a may include a conductive material, for example, a metal material such as tungsten (W), copper (Cu), and/or aluminum (Al), and the barrier layers 253b and 254b may include, for example, at least one of titanium (Ti), titanium nitride (TiN), tantalum (Ta), tantalum nitride (TaN), tungsten nitride (WN), and/or tungsten carbon nitride (WCN).

The gate contact plugs 252 may be disposed in the connection region CA of the second region R2 and may extend in a vertical direction, for example, in the Z-direction. The gate contact plugs 252 may be connected to ends or contacts by a staircase form of the gate electrodes 230. The gate contact plugs 252 may be connected to the upper interconnection structure 270 in a lower portion. In some example embodiments, the gate contact plugs 252 may penetrate through the gate electrodes 230. In this case, upper ends of the gate contact plugs 252 may be disposed in an insulating region in the second substrate 201 or in an insulating region penetrating through the second substrate 201.

The source contact plug 253 may be spaced apart from the second substrate 201 on an external side of the second substrate 201 and may extend in a vertical direction, for example, a Z-direction. A lower surface of the source contact plug 253 may be disposed on a level lower than a level of the lowermost gate electrode 230 among the gate electrodes 230 with respect to an upper surface of the first substrate 101. The source contact plug 253 may penetrate through the upper capping layer 290 and may be connected to the source contact pad 261. In example embodiments, an upper surface of the source contact plug 253 may be disposed on a level lower than a level of the second substrate 201, and an upper surface of the source contact plug 253 may be in contact with the source contact pad 261. A lower surface of the source contact plug 253 may be connected to an upper interconnection structure 270. A width of an upper surface of the source contact plug 253 may be less than a width of the lower surface. The source contact plug 253 may be formed in the same process as a process of forming the peripheral contact plug 254, and may have a shape the same as or similar to a shape of the peripheral contact plug 254.

The peripheral contact plug 254 may be spaced apart from the second substrate 201 and the source contact plug 253 on an external side of the second substrate 201 and may extend in a vertical direction, for example, in the Z-direction. The peripheral contact plug 254 may penetrate through the upper capping layer 290 and may be connected to the peripheral contact pad 260. An upper surface of the peripheral contact plug 254 may be in contact with the peripheral contact pad 260. The peripheral contact plug 254 may be connected to the upper interconnection structure 270. An upper surface of the peripheral contact plug 254 and an upper surface of the source contact plug 253 may be disposed on substantially the same level with respect to an upper surface of the first substrate 101, but example embodiments thereof are not limited thereto.

The via patterns 265 may be disposed on the second substrate 201. The via patterns 265 may be formed on the second substrate 201 of the connection region CA and/or the memory cell array region MCA. The via patterns 265 may be spaced apart from each other in a constant distance in the X and Y-directions and a plurality of the via patterns 265 may be disposed. As illustrated in FIGS. 2A to 2C, the via patterns 265 may be alternately disposed without overlapping the channel structures CH in the Z-direction, but example embodiments thereof are not limited thereto. In FIG. 2A, relative sizes of the via patterns 265 and the channel structures CH may not be limited to the illustrated example, and in example embodiments, the via patterns 265 may have a size greater or less than that of the channel structures CH. At least a portion of lower surfaces of each of the via patterns 265 may be disposed on a level higher than a level of a lower surface of the source contact via 266 with respect to the bottom surface of the second substrate 201. For example, as illustrated in FIG. 2C, a level L1 of the lower surfaces of each of the via patterns 265 may be higher than a level L2 of the lower surface of the source contact via 266. Also, the level may be higher than the level L2 of the lower surface of the peripheral contact via 267. In the drawing, the level L2 of the lower surface of the peripheral contact via 267 and the level L2 of the lower surface of the source contact via 266 may be the same, or may be different.

The via patterns 265 may be connected to an upper portion of the second substrate 201 and may extend from the second substrate 201 in a vertical direction, for example, in a Z-direction. In each of the via patterns 265, a width of the upper portion may be greater than a width of the lower portion.

An upper surface of each of the via patterns 265 may be in contact with the interconnection line 299. The via patterns 265, together with the interconnection line 299, may work as a connection contact layer for electrically connecting the second substrate 201 to the source contact plug 253. That is, even when the source contact plug 253 is not directly connected to the second substrate 201, since the via patterns 265 and the interconnection line 299 may provide an electrical connection path between the source contact plug 253 and the second substrate 201, the source contact plug 253 and the second substrate 201 may be electrically connected to each other.

The via patterns 265 may include a material different from that of the second substrate 201. For example, the via patterns 265 may include at least one of a metal material such as aluminum (Al), copper (Cu), tungsten (W), cobalt (Co), ruthenium (Ru) and molybdenum (Mo) and a metal nitride such as titanium nitride (TiN), tantalum nitride (TaN), and/or tungsten nitride (WN). The second substrate 201 may include a semiconductor material. Since the via patterns 265 include a metal material, contact resistance may be lowered as compared to the example in which the via patterns 265 include a semiconductor material. A boundary between the via patterns 265 and the second substrate 201 may be distinct.

As for the source contact via 266 and the peripheral contact via 267, a width of a lower portion thereof may be less than a width of an upper portion. The source contact via 266 may be formed on the source contact pad 261 of the external region PA. The peripheral contact via 267 may be formed on the peripheral contact pad 260 of the external region PA. In example embodiments, the source contact via 266 and the peripheral contact via 267 may include aluminum (Al). The source contact via 266 may be connected to an interconnection line 299 of the external region PA. A peripheral contact via 267 may be connected to the conductive pad 300. The peripheral contact via 267 may include a plurality of vias connected to the conductive pad 300. The source contact via 266 and the peripheral contact via 267 may be formed of a metal material, and may include, for example, tungsten (W) or aluminum (Al).

The source contact pad 261 and the source contact via 266 may be disposed on the source contact plug 263. The source contact pad 261 may be horizontally spaced apart from the peripheral contact pad 260 and the second substrate 201 in the external region PA. The source contact pad 261 may be disposed on a level on which at least a portion may overlap the second substrate 201. For example, a lower surface of the source contact pad 261 may be coplanar with a lower surface of the second substrate 201. The source contact pad 261 may be in contact with an upper surface of the source contact plug 253, but example embodiments thereof are not limited thereto. The source contact pad 261 may be in contact with a lower surface of the source contact plug 253 and the source contact via 266, but example embodiments thereof are not limited thereto. The source contact via 266 may be disposed on the source contact pad 261 and may be connected to the interconnection line 299. The source contact pad 261 may include a material different from that of the second substrate 201. In example embodiments, the source contact via 266 may include tungsten (W).

The peripheral contact pad 260 and the peripheral contact via 267 may be disposed on the peripheral contact plug 254. The peripheral contact pad 260 may be spaced apart from the source contact pad 261 and the second substrate 201 in the external region PA. The peripheral contact pad 260 may be in contact with an upper surface of the peripheral contact plug 254, but example embodiments thereof are not limited thereto. A peripheral contact via 267 may be disposed on the peripheral contact pad 260 and may be connected to the conductive pad 300. In example embodiments, the peripheral contact via 267 may include tungsten (W).

The interconnection line 299 may be disposed on the second substrate 201. The interconnection line 299 may be disposed on a level higher than a level of the upper surface of the second substrate 201 with respect to an upper surface of the first substrate 101. The interconnection line 299 may electrically connect the via patterns 265 to the source contact plug 253. The interconnection lines 299 may be in contact with an upper surface of each of the via patterns 265 and the upper surface of the source contact via 266. The interconnection line 299 may include a conductive material, and may include, for example, a metal material such as tungsten (W), copper (Cu), aluminum (Al), gold (Au), or silver (Ag). In example embodiments, the interconnection line 299 may include at least one region having a lattice shape or a line shape on the upper surface of the second substrate 201, but example embodiments thereof are not limited thereto.

When the source contact plug 253 is directly connected to the edge portion EP of the second substrate 201, a semiconductor material layer of the second substrate 201 may provide an electrical connection path from the edge portion EP of the second substrate 201 to the channel structure CH of the memory cell array region MCA. The electrical connection path may have a length of approximately from the edge portion EP of the second substrate 201 to the channel structure CH of the memory cell array region MCA. In this case, since the semiconductor material layer has a relatively higher electrical resistance than that of the metal material layer, noise generated by the resistive element of the second substrate 201 may interfere with performance of an operation (e.g., a read operation) of the memory cell. For example, when a current flows through the common source line of the second substrate 201, a resistive element of the second substrate 201 may cause a voltage drop in the common source line, such that a read operation of the memory cell may not be properly performed. In example embodiments, a source contact plug 253 may be electrically connected to an interconnection line 299 formed of a metal material through a source contact via 266, the interconnection line 299 may be widely disposed on the upper surface of the second substrate 201, and the interconnection line 299 may be electrically connected to the second substrate 201 through the via patterns 265, such that the source contact plug 253 may be electrically connected to the second substrate 201. Accordingly, since a metal material layer of the interconnection line 299, which has a relatively low electrical resistance, may provide an electrical connection path from the source contact plug 253 of the external region PA to the channel structure CH of the memory cell array region MCA, a length of the electrical connection path by the semiconductor material layer of the second substrate 201 having relatively high electrical resistance may be reduced. Accordingly, since a resistive element of the common source line of the second substrate 201 may be reduced, noise generated by the common source line during operation of the memory cell may be reduced, and electrical characteristics and reliability of the semiconductor device may be improved.

The conductive pad 300 may be configured as an input/output pad of the semiconductor device 100, and may be electrically connected to a controller. The conductive pad 300 may be disposed on the upper insulating layer 295. The conductive pad 300 may be in contact with the peripheral contact via 267. The conductive pad 300 may be electrically connected to the peripheral contact via 267 on the peripheral contact plug 254. The conductive pad 300 may be electrically connected to the circuit devices 120 of the peripheral circuit region PERI. The conductive pad 300 may be spaced apart from the interconnection line 299 in the external region PA. The conductive pad 300 may include the same material as that of the interconnection line 299. In example embodiments, the conductive pad 300 may include aluminum (Al). The conductive pad 300 may be disposed on substantially the same level as a level of the interconnection line 299. Also, the conductive pad 300 may be formed of substantially the same material as that of the interconnection line 299. However, example embodiments thereof are not limited thereto, and the conductive pad 300 may be disposed on a level higher than a level of the interconnection line 299.

The upper interconnection structure 270 may electrically connect the gate electrodes 230, the channel structures CH, the second substrate 201, and the conductive pad 300 to the circuit devices 120. The upper interconnection structure 270 may include a channel contact plug 271, a gate contact stud 272, a source contact stud 273, a peripheral contact stud 274, an upper contact plug 275, and an upper interconnection line 277. The channel contact plug 271 may be connected to the channel pad 249 of the channel structure CH. The channel contact plug 271 may be electrically connected to the channel layer 240 through the channel pad 249 of the channel structures CH in the memory cell array region MCA. The gate contact stud 272 may be connected to the gate contact plug 252. The source contact stud 273 may be connected to the source contact plug 253. The peripheral contact stud 274 may be connected to the peripheral contact plug 254. The upper contact plugs 275 may be connected to a channel contact plug 271, a gate contact stud 272, a source contact stud 273, and a peripheral contact stud 274. An upper interconnection line 277 may be connected to an upper contact plug 275. The upper interconnection structure 270 may include a conductive material, for example, tungsten (W), copper (Cu), aluminum (Al), and the like, and each component may include a diffusion barrier including at least one of titanium (Ti), titanium nitride (TiN), tantalum (Ta, tantalum nitride (TaN), and tungsten nitride (WN). In example embodiments, the number of layers of the upper contact plugs 275 and the upper interconnection lines 277 included in the upper interconnection structure 270 and the arrangement form thereof may be varied.

The upper bonding structure 280 may be connected to the upper interconnection structure 270. For example, the gate contact stud 272 and the channel contact plug 271 may be electrically connected to the upper bonding structure 280. The upper bonding structure 280 may include an upper bonding via 282, an upper bonding pad 284, and an upper bonding insulating layer 286. The upper bonding via 282 may be connected to the upper interconnection structure 270. The upper bonding pad 284 may be connected to the upper bonding via 282. The upper bonding via 282 and the upper bonding pad 284 may include a conductive material, for example, tungsten (W), copper (Cu), and/or aluminum (Al), and each component may further include a diffusion barrier. The upper bonding insulating layer 286 may also function as a diffusion barrier of the upper bonding pad 284 and may include at least one of SiCN, SiO, SiN, SiOC, SiON and SiOCN. The upper bonding insulating layer 286 may have a thickness less than that of the upper bonding pad 284, but example embodiments thereof are not limited thereto.

The upper capping layer 290 may be disposed below the second substrate 201 and may cover or overlap the second substrate 201, the upper insulating layer 295, and the gate electrodes 230. The upper capping layer 290 may include a plurality of insulating layers. The upper capping layer 290 may include an insulating material such as silicon oxide, silicon nitride, silicon oxynitride, or silicon oxycarbide.

An upper insulating layer 295 may be disposed on the second substrate 201. The upper insulating layer 295 may cover or overlap the second substrate 201, the source contact pad 261, and the peripheral contact pad 260. The upper insulating layer 295 may include an insulating material such as silicon oxide, silicon nitride, silicon oxynitride, or silicon oxycarbide.

In the description of the example embodiments as below, the same reference numerals as those in FIGS. 1 to 2c may denote corresponding components, and the descriptions overlapping the descriptions described above will not be provided.

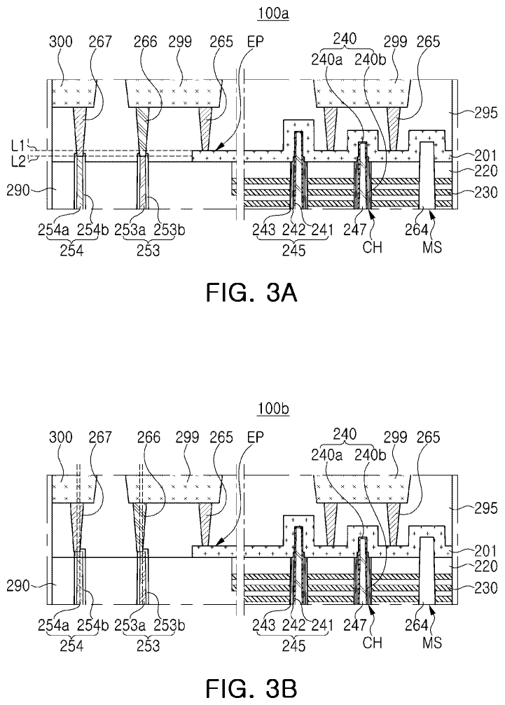

FIGS. 3A, 3B, 4, 5A and 5B are enlarged cross-sectional diagrams illustrating a portion of a semiconductor device according to example embodiments, illustrating a region corresponding to FIG. 2C.

Referring to FIG. 3A, the semiconductor device 100a may not include the source contact pad 261 and/or the peripheral contact pad 260 in the example embodiments in FIG. 2C. In FIG. 3A, both the source contact pad 261 and the peripheral contact pad 260 may not be included as a non-limiting example, but at least one of the source contact pad 261 and the peripheral contact pad 260 may not be included. Each of the source contact plug 253 and peripheral contact plug 254 may penetrate through the upper capping layer 290 and the upper insulating layer 295. In example embodiments, an upper surface of the source contact plug 253 and an upper surface of the peripheral contact plug 254 may be disposed on a level higher than a level of the lower surface of the second substrate 201. FIG. 3A illustrates the example in which the upper surface of the source contact plug 253 and the upper surface of the peripheral contact plug 254 are disposed on substantially the same level, but example embodiments thereof are not limited thereto. In example embodiments, a level L1′ of the lower surface of the via patterns 265 may be substantially the same as a level L2′ of the lower surface of the source contact via 266 and a level L2′ of the lower surface of the peripheral contact via 267, but example embodiments thereof is not limited thereto. In FIG. 3A, the level L2′ of the lower surface of the source contact via 266 and the level L2′ of the lower surface of the peripheral contact via 267 may be substantially the same, but example embodiments thereof is not limited thereto.

Referring to FIG. 3B, in the semiconductor device 100b in FIG. 3A, a central axis of the source contact via 266 and a central axis of the source contact plug 253 may be shifted, and a central axis of the peripheral contact via 267 and a central axis of the peripheral contact plug 254 may be shifted, which may also be applied to a semiconductor device including the source contact pad 261 and/or the peripheral contact pad 260.

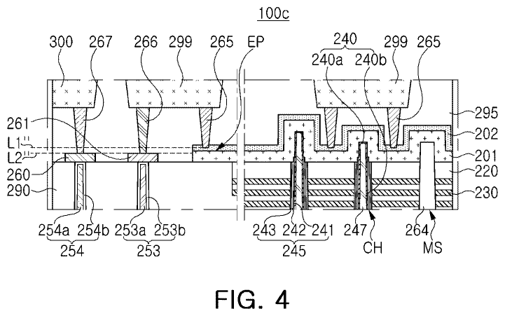

Referring to FIG. 4, a semiconductor device 100c may further include a conductive plate 202 in the semiconductor device 100 in FIG. 2C. The conductive plate 202 may cover or overlap the second substrate 201 and may include a material different from that of the second substrate 201. Since the conductive plate 202 may include a metal material such as tungsten (W), copper (Cu), or aluminum (Al), contact resistance may be lowered as compared to the example in which the second substrate 201 including a semiconductor material and the via patterns 265 are in contact with each other. The boundary between the via patterns 265 and the second substrate 201 may be distinct. In example embodiments, each of the via patterns 265 may penetrate through at least a portion of the conductive plate 202. For example, a level L1″ of the lower surface of via patterns 265 may be disposed on a level higher than a level L2″ of the lower surface of the source contact via 266 and a level L2″ of the lower surface of the peripheral contact via 267, but example embodiments thereof are not limited thereto. In FIG. 4, the level L2″ of the lower surface of the source contact via 266 and the level L2″ of the lower surface of the peripheral contact via 267 may be substantially the same, but example embodiments thereof are not limited thereto. The conductive plate 202 may have a curved structure or protruding structure along the upper surface of the second substrate 201. Since the conductive plate 202 is disposed on the second substrate 201, the conductive plate 202 may be disposed apart from the source contact via 266, the source contact pad 261, and the source contact plug 253 disposed in the external region PA of the second substrate 201.

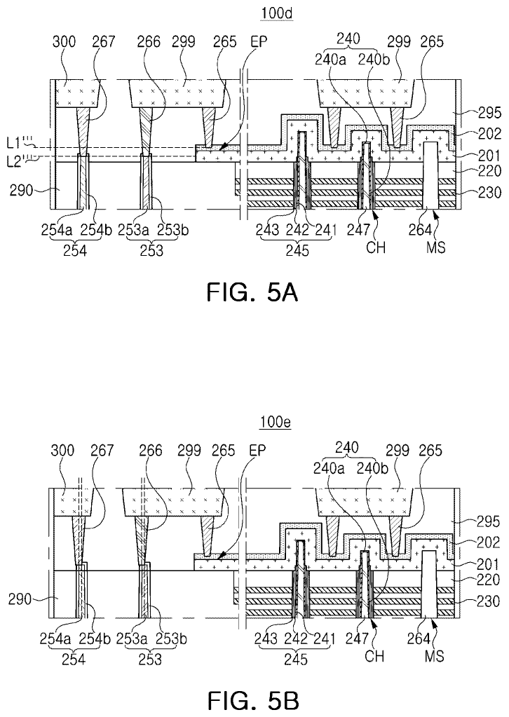

Referring to FIG. 5A, a semiconductor device 100d may not include a source contact pad 261 and/or a peripheral contact pad 260 in the semiconductor device 100c in FIG. 4. In FIG. 5A, both the source contact pad 261 and the peripheral contact pad 260 may not be included, or at least one of the source contact pad 261 and the peripheral contact pad 260 may not be included. Each of the source contact plug 253 and the peripheral contact plug 254 may penetrate through the upper capping layer 290 and the upper insulating layer 295. In example embodiments, an upper surface of the source contact plug 253 and an upper surface of the peripheral contact plug 254 may be disposed on a level higher than a level of the lower surface of the second substrate 201. In FIG. 5A, the upper surface of the source contact plug 253 and the upper surface of the peripheral contact plug 254 may be disposed on substantially the same level, but example embodiments thereof are not limited thereto. In example embodiments, a level L1′″ of a lower surface of the via patterns 265 may be substantially equal to a level L2′″ of a lower surface of the source contact via 266 and a level L2′″ of a lower surface of the peripheral contact via 267, but example embodiments thereof are not limited thereto. In FIG. 5A, the level L2′″ of the lower surface of the source contact via 266 and the level L2″′ of the lower surface of the peripheral contact via 267 may be substantially the same, but example embodiments thereof are not limited thereto.

Referring to FIG. 5B, in the semiconductor device 100e, in the semiconductor device 100d in FIG. 5A, a central axis of the source contact via 266 and a central axis of the source contact plug 253 may be shifted, and a central axis of the peripheral contact via 267 and a central axis of the peripheral contact plug 254 may be shifted, which may also be applied to a semiconductor device including the source contact pad 261 and/or the peripheral contact pad 260.

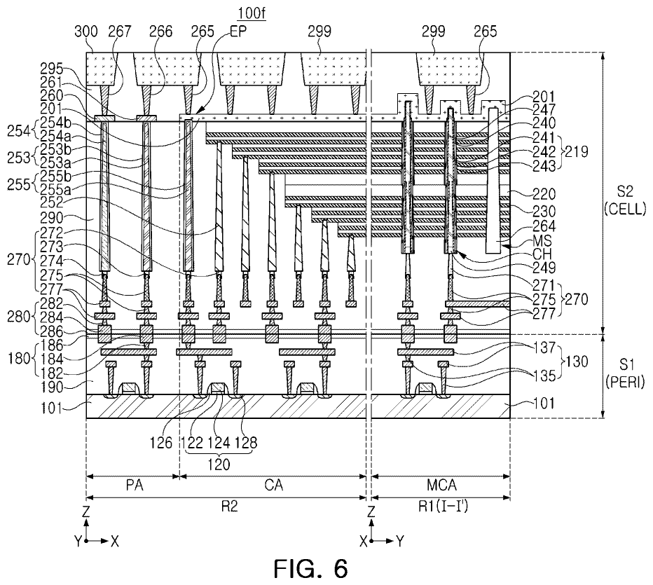

Referring to FIG. 6, a semiconductor device 100f may further include a substrate contact plug 255 in the semiconductor device 100 in FIG. 2B. The substrate contact plug 255 may be in direct contact with the edge portion EP of the second substrate 201. The substrate contact plug 255 may have a cylindrical shape or a truncated cone shape, and a width may decrease toward an upper portion depending on an aspect ratio. The substrate contact plug 255 may penetrate through a portion of the upper capping layer 290. The substrate contact plug 255 may include a conductive layer and a barrier layer surrounding side surfaces and one end of the conductive layer. For example, the substrate contact plug 255 may include a conductive layer 255a and a barrier layer 255b, and the barrier layer 255b may surround upper and side surfaces of the conductive layer 255a in plan view. The conductive layer 255a may include a conductive material, for example, a metal material such as tungsten (W), copper (Cu), or aluminum (Al), and the barrier layer 255b may include, for example, titanium (Ti), titanium nitride (TiN), tantalum (Ta), tantalum nitride (TaN), tungsten nitride (WN), and/or tungsten carbon nitride (WCN).

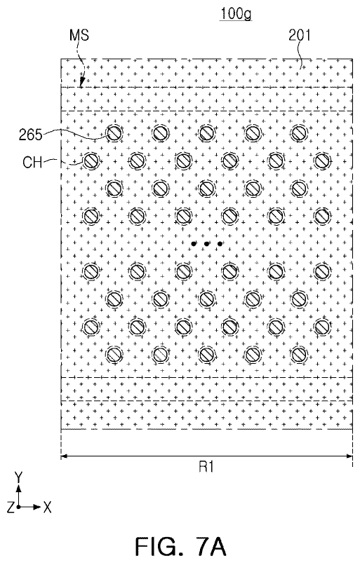

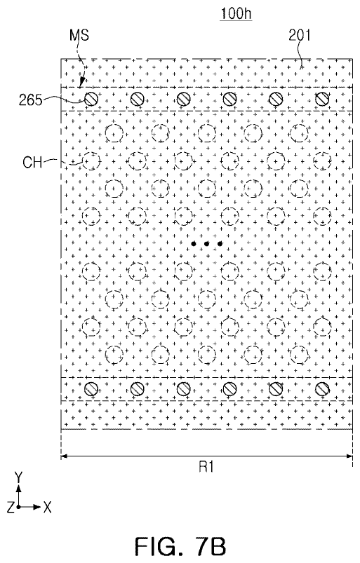

FIGS. 7A and 7B are plan diagrams illustrating a portion of a semiconductor device according to an example embodiment, illustrating a region corresponding to FIG. 2A.

Referring to FIG. 7A, in a semiconductor device 100g, via patterns 265 may be disposed on channel structures CH, respectively. In example embodiments, each of the via patterns 265 may overlap the channel structures CH in the Z-direction, respectively. Although not illustrated, the via patterns 265 may be disposed on the second substrate 201 in the second region R2 as illustrated in FIG. 2B.

Referring to FIG. 7B, in semiconductor device 100h, via patterns 265 may be disposed on isolation regions MS, respectively, and may overlap isolation regions MS in the Z-direction. In example embodiments, each of the via patterns 265 may be spaced apart from the channel structures CH in the Z-direction without overlapping the channel structures CH. Although not illustrated, the via patterns 265 may be disposed on the second substrate 201 in the second region R2 as illustrated in FIG. 2B.

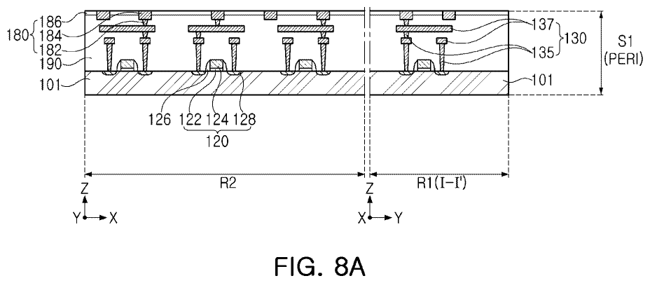

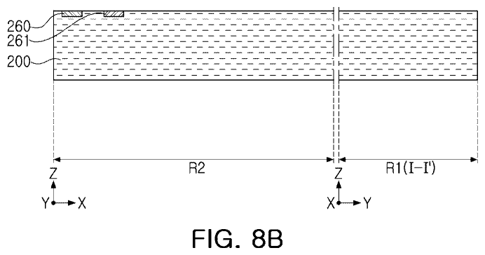

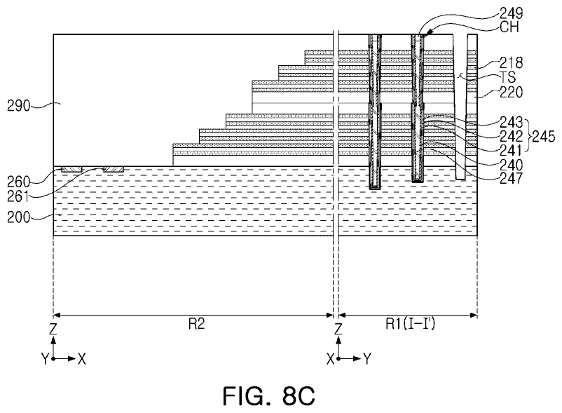

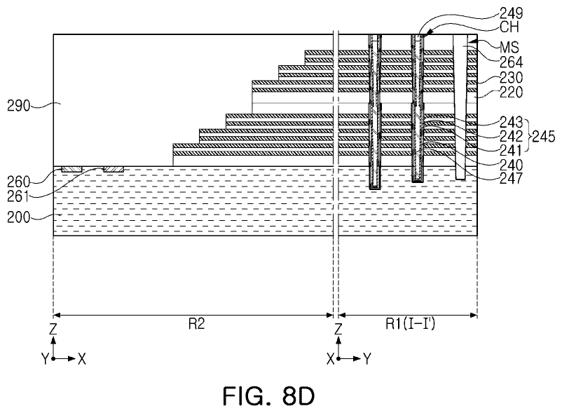

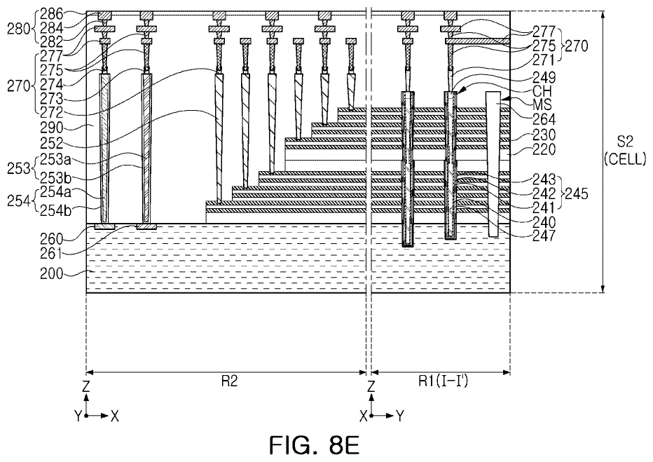

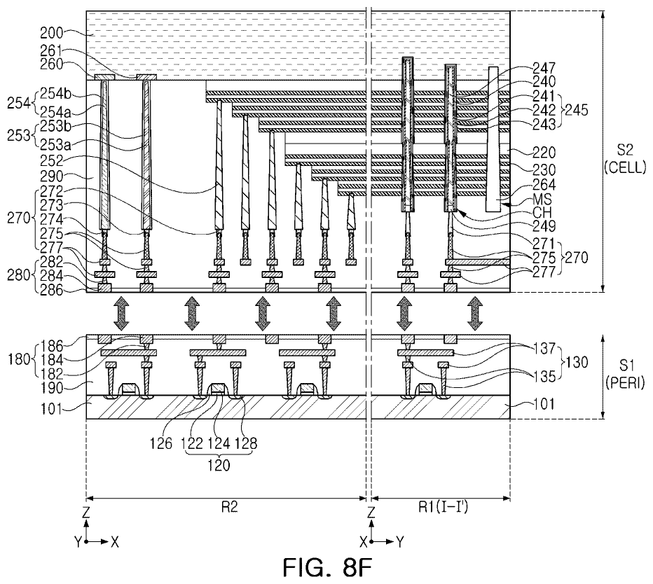

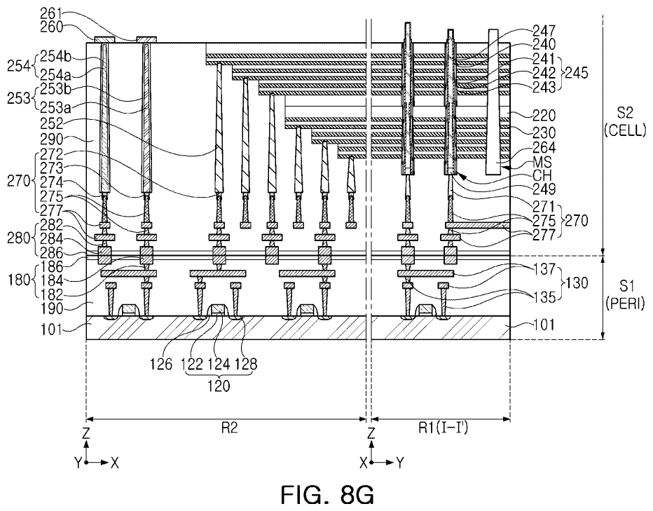

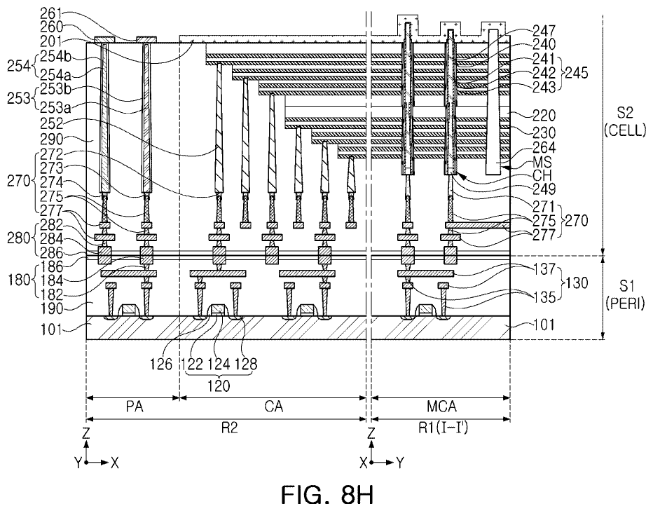

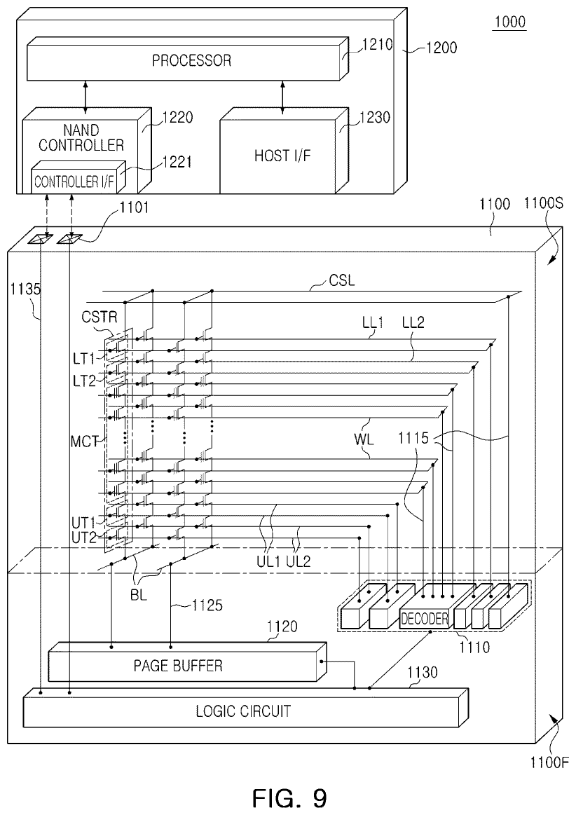

FIGS. 8A, 8B, 8C, 8D, 8E, 8F, 8G and 8H are cross-sectional diagrams illustrating a method of manufacturing a semiconductor device according to example embodiments, illustrating regions corresponding to the region illustrated FIG. 2B.

Referring to FIG. 8A, a first semiconductor structure S1 including circuit devices 120 included in a peripheral circuit region PERI, a lower interconnection structure 130, a lower bonding structure 180, and a lower capping layer 190 may be formed on a first substrate 101.

First, device isolation layers may be formed in the first substrate 101, and a circuit gate dielectric layer 122 and a circuit gate electrode 124 may be formed in order on the first substrate 101. The device isolation layers may be formed by, for example, a shallow trench isolation (STI) process. A circuit gate dielectric layer 122 may be formed on the first substrate 101, and a circuit gate electrode 124 may be formed on the circuit gate dielectric layer 122. The circuit gate dielectric layer 122 and the circuit gate electrode 124 may be formed using atomic layer deposition (ALD) or chemical vapor deposition (CVD). The circuit gate dielectric layer 122 may be formed of silicon oxide, and the circuit gate electrode 124 may be formed of at least one of polycrystalline silicon or a metal silicide layer, but example embodiments thereof are not limited thereto. Thereafter, spacer layers 126 may be formed on both sidewalls of the circuit gate dielectric layer 122 and the circuit gate electrode 124, and the source/drain regions 128 may be formed by filling the active region of the first substrate 101 with impurities on both sides of the circuit gate electrode 124.

Among the lower interconnection structure 130, the lower contact plugs 135 may be formed by forming a portion of the lower capping layer 190, removing the portion by etching, and filling the portion with a conductive material. The lower interconnection lines 137 may be formed by, for example, depositing a conductive material and patterning the material.

Among the lower bonding structure 180, the lower bonding via 182 may be formed by forming a portion of the lower capping layer 190, removing the portion by etching, and filling the portion with a conductive material. The lower bonding pad 184 may be formed by, for example, depositing a conductive material and patterning the material. The lower bonding structure 180 may be formed by, for example, a deposition process or a plating process. The lower bonding insulating layer 186 may be formed by covering portions of an upper surface and a side surface of the lower bonding pad 184 and performing a planarization process until the upper surface of the lower bonding pad 184 is exposed.

The lower capping layer 190 may include a plurality of insulating layers. The lower capping layer 190 may become a portion in processes of forming the lower interconnection structure 130 and the lower bonding structure 180. Accordingly, the first semiconductor structure S1, which is the peripheral circuit region PERI, may be formed.

Referring to FIG. 8B, a peripheral contact pad 260 and a source contact pad 261 may be formed on the base substrate 200. The base substrate 200 may include a semiconductor material, for example, a group IV semiconductor, a group III-V compound semiconductor, or a group II-VI compound semiconductor. The base substrate 200 may be provided to control a thickness of the second substrate 201 in the process of removing the base substrate 200 described below.

A peripheral contact pad 260 and a source contact pad 261 may be formed in the base substrate 200 by patterning the base substrate 200. The peripheral contact pad 260 and the source contact pad 261 may work as an etch stop layer in a subsequent process of forming the peripheral contact plug 254 and the source contact plug 253 of FIG. 8E.

A process of forming the peripheral contact pad 260 and the source contact pad 261 may be optional. For example, when the semiconductor device in FIGS. 3A, 3B, 5A, and 5B is manufactured, the process of forming the peripheral contact pad 260 and the source contact pad 261 in the base substrate 200 may not be performed, but example embodiments thereof are not limited thereto. In some embodiments, the semiconductor device in FIGS. 3A, 3B, 5A, and 5B may be manufactured by performing a process of forming a peripheral contact pad 260 and a source contact pad 261, and performing a process of removing the peripheral contact pad 260 and the source contact pad 261 in the process in FIG. 8G.

Referring to FIG. 8C, a lower stack structure may be formed by alternately stacking the sacrifice insulating layers 218 and the interlayer insulating layers 220, and an upper stack structure may be formed by alternately stacking the sacrifice insulating layers 218 and the interlayer insulating layers 220. Thereafter, channel structures CH penetrating through a stack structure of the sacrifice insulating layers 218 and the interlayer insulating layers 220 may be formed. An isolation opening TS penetrating through the stack structure of the sacrifice insulating layers 218 and the interlayer insulating layers 220 may be formed in a region corresponding to the isolation region MS (see FIG. 2B).

A portion of the sacrifice insulating layers 218 may be replaced with gate electrodes 230 (see FIG. 2B) through a subsequent process. The sacrifice insulating layers 218 may be formed of a material different from that of the interlayer insulating layers 220, and may be formed of a material etched with etch selectivity under specific etching conditions with respect to the interlayer insulating layers 220. For example, the interlayer insulating layer 220 may be formed of at least one of silicon oxide and silicon nitride, and the sacrifice insulating layers 218 may be formed of a material different from that of the interlayer insulating layer 220 selected from silicon, silicon oxide, silicon carbide, and silicon nitride. In example embodiments, the interlayer insulating layers 220 may not have the same thickness. The thickness of the interlayer insulating layers 220 and the sacrifice insulating layers 218 and the number of films forming the same may be varied from the illustrated example.

In the second region R2, a photolithography process and an etching process for the sacrifice insulating layers 218 may be repeatedly performed using a mask layer such that the sacrifice insulating layers 218 of the upper portion may extend shorter than the sacrifice insulating layers 218 of the lower portion. Accordingly, the sacrifice insulating layers 218 may form a step structure having a staircase shape by a predetermined unit.

Vertical sacrificial structures may be formed to penetrate through the lower stack structure. The vertical sacrificial structures may be formed by anisotropically etching the lower stack structure of the sacrifice insulating layers 218 and the interlayer insulating layers 220 using a mask layer, and may be formed by forming lower channel holes having a hole shape and filling the holes. The vertical sacrificial structures may be formed such that at least a portion thereof may be recessed into the base substrate 200 at different depths, but example embodiments thereof are not limited thereto. The vertical sacrificial structure may include a semiconductor material such as polycrystalline silicon. In example embodiments, the vertical sacrificial structure may include at least one of silicon oxide, silicon nitride, and/or silicon oxynitride. After the vertical sacrificial structure is formed, an upper stack structure of the sacrifice insulating layers 218 and the interlayer insulating layers 220 may be formed on the lower stack structure and the vertical sacrificial structure.

Thereafter, an upper capping layer 290 covering or overlapping the stack structure of the sacrifice insulating layers 218 and interlayer insulating layers 220 may be partially formed.

The channel structures CH may be formed by forming upper holes in the vertical sacrificial structure, forming channel holes in a hole shape by removing the vertical sacrificial structure, and filling the channel holes with a plurality of layers. The plurality of layers may include a channel dielectric layer 245, a channel layer 240, a channel buried insulating layer 247, and a channel pad 249. Upper channel holes of the channel holes may be formed by anisotropically etching the upper stack structure of the sacrifice insulating layers 218 and the interlayer insulating layers 220 using a mask layer. Lower channel holes of the channel holes may be formed by removing a vertical sacrificial structure exposed through the upper channel holes.

Due to a height of the stack structure, the sidewall of the channel structures CH may not be perpendicular to an upper surface of the base substrate 200. The channel structures CH may be formed to be recessed into a portion of the base substrate 200.

The channel dielectric layer 245 may be formed to have a uniform thickness. In this process, the entirety or a portion of the channel dielectric layer 245 may be formed, and a portion extending perpendicularly to the second substrate 201 along the channel structures CH (see FIG. 2B) may be formed in this process. The channel layer 240 may be formed on the channel dielectric layer 245 in the channel structures CH. The channel buried insulating layer 247 may be formed to fill the channel structures CH and may be formed of an insulating material. The channel pad 249 may be formed of a conductive material, for example polycrystalline silicon.

Referring to FIG. 8D, the gate electrodes 230 may be formed by removing the insulating layers (218 in FIG. 8C) through an isolation opening (TS in FIG. 8C). An isolation region MS may be formed in an isolation opening (TS in FIG. 8C).

Tunnel portions may be formed by removing the sacrifice insulating layers 218 through the isolation opening (TS in FIG. 8C), and gate electrodes 230 may be formed by filling the tunnel portions with a conductive material. The conductive material may include a metal, polycrystalline silicon or metal silicide material. After forming the gate electrodes 230, the conductive material deposited in the isolation opening TS may be removed through an additional process, and an insulating material and a conductive material may be filled therein, thereby forming an isolation region MS.

Referring to FIG. 8E, an upper interconnection structure 270 including gate contact plugs 252, source contact plugs 253, peripheral contact plugs 254, and channel contact plugs 271 may be formed, and an upper bonding structure 280 may be formed.

In the first region R1, channel contact plugs 271 may be formed to be connected to the channel structures CH. In the second region R2, the gate contact plugs 252 may be connected to the gate electrodes 230, and the source contact plugs 253 and the peripheral contact plugs 254 may be connected to the base substrate 200. The gate contact plugs 252, and the source contact plugs 253, and the peripheral contact plugs 254 may be formed to different depths, or may be formed by simultaneously forming contact holes using an etch stop layer, and filling the contact holes with a conductive material. However, in example embodiments, a portion of the gate contact plugs 252, the source contact plugs 253, and the peripheral contact plugs 254 may be formed in different processes.

The contact studs 272, 273, and 274 may be formed to be connected to the gate contact plugs 252, the source contact plugs 253, and the peripheral contact plugs 254, respectively. The upper contact plugs 275 may be formed on the contact studs 272, 273, and 274 and may connect the upper interconnection lines 277 to each other vertically.

Thereafter, the upper bonding structure 280 may be formed in a similar manner to forming the lower bonding structure 180. Accordingly, a second semiconductor structure S2 which is a memory cell region CELL may be formed. However, in the process of manufacturing a semiconductor device, the memory cell region CELL may further include the base substrate 200.

Referring to FIG. 8F, a first semiconductor structure S1, which is a peripheral circuit region PERI, and a second semiconductor structure S2, which is a memory cell region CELL may be bonded to each other.

The peripheral circuit region PERI and the memory cell region CELL may be connected to each other by bonding the lower bonding pad 184 to the upper bonding pad 284 by pressure. The lower bonding insulating layer 186 and the upper bonding insulating layer 286 may be connected to each other by bonding by applying pressure. The memory cell region CELL may be turned over on the peripheral circuit region PERI such that the upper bonding pad 284 may be bonded to face down. The peripheral circuit region PERI and the memory cell region CELL may be directly bonded to each other without using an adhesive such as an adhesive layer therebetween.

Referring to FIG. 8G, the base substrate 200 and the channel dielectric layer 245 on the channel structure CH may be removed. First, the base substrate 200 may be removed. A portion of the base substrate 200 may be removed from the upper surface by a polishing process such as a grinding process, and the other portion may be removed by an etching process such as wet etching and/or dry etching. Alternatively, the entire base substrate 200 may be removed by an etching process. In the region from which the base substrate 200 is removed, the source contact plug 253, the peripheral contact plug 254, and the channel structures CH may have a protruding shape.

Thereafter, the channel dielectric layer 245 on the channel structure CH may be removed. The channel dielectric layer 245 may be removed by a photolithography process and an etching process such as wet etching and/or dry etching. Accordingly, the channel layer 240 may be in contact with the second substrate 201 when a subsequent process is performed.

Referring to FIG. 8H, a second substrate 201 may be formed.

N-type doped polysilicon may be deposited on the upper capping layer 290 and the uppermost interlayer insulating layer 220 in a region other than the external region PA including the source contact plug 253 and the peripheral contact plug 254 in the second region R2, thereby forming the second substrate 201. However, example embodiments thereof are not limited thereto and may be formed by depositing P-type doped polysilicon. For example, the second substrate 201 may be formed in a region other than the region in which the source contact plug 253 and the peripheral contact plug 254 are present using a mask layer. The second substrate 201 may be formed to cover or overlap the channel structures CH and the isolation region MS. The second substrate 201 may be formed along the protruding channel layer 240, but example embodiments thereof are not limited thereto. Accordingly, the second substrate 201 and the channel layer 240 may be electrically connected to each other.

Thereafter, referring to FIG. 2B together, a portion of the upper insulating layer 295 may be formed, and the via patterns 265, the source contact via 266, and the peripheral contact via 267 may be formed. The via patterns 265, the source contact via 266, and the peripheral contact via 267 may be formed by forming a via hole penetrating through a portion of the upper insulating layer 295 and filling the via hole with a conductive material. Each of the via patterns 265, the source contact via 266, and the peripheral contact via 267 may be in contact with the second substrate 201, the source contact pad 261, and the peripheral contact pad 260, respectively. The conductive pad 300 and the interconnection line 299 may also be formed by partially removing the upper insulating layer 295 and filling the region with a conductive material. Accordingly, the semiconductor device 100 in FIGS. 1 to 2C may be manufactured.

FIG. 9 is a diagram illustrating a data storage system including a semiconductor device according to example embodiments.

Referring to FIG. 9, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiments with reference to FIGS. 1 to 7B. The semiconductor device 1100 may include a first structure 1100F and a second structure 1100S on the first structure 1100F. In the example embodiments, the first structure 1100F may be disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bit line BL, a common source line CSL, word lines WL, first and second gate upper lines UL1 and UL2, first and second gate lower lines LL1 and LL2 and memory cell strings CSTR disposed between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in the example embodiments.

In the example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The word lines WL may be configured as gate electrodes of the memory cell transistors MCT, and the gate upper lines UL1 and UL2 may be configured as gate electrodes of the upper transistors UT1 and UT2, respectively.

In the example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from the first structure 1100F to the second structure 1100S. The bit lines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In the example embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a NAND interface 1221 processing communication with the semiconductor device 1100. Through the NAND interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

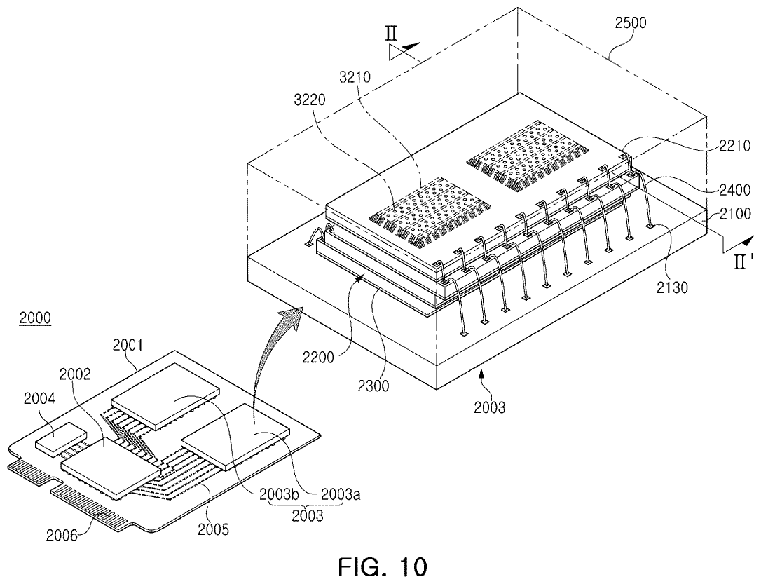

FIG. 10 is a perspective diagram illustrating a data storage system including a semiconductor device according to example embodiments.

Referring to FIG. 10 a data storage system 2000 in example embodiments may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host. The number and arrangement of the plurality of pins in the connector 2006 may vary depending on a communication interface between the data storage system 2000 and the external host. In the example embodiments, the data storage system 2000 may communicate with an external host according to one of interfaces from among universal serial bus (USB), peripheral component interconnect express PCI-Express), serial advanced technology attachment (SATA, M-Phy for universal flash storage (UFS). In the example embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering or overlapping the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 9. Each of the semiconductor chips 2200 may include gate stack structures 3210 and channel structures 3220. Each of the semiconductor chips 2200 may include the semiconductor device described in the aforementioned example embodiments with reference to FIGS. 1 to 7B.

In the example embodiments, the connection structure 2400 may be configured as a bonding wire electrically connecting the input/output pad 2210 to the package upper pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In the example embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In the example embodiments, the controller 2002 and the semiconductor chips 2200 may be included in a single package. In example embodiments, the controller 2002 and the semiconductor chips 2200 may be mounted on a separate interposer substrate different from the main board 2001, and the controller 2002 and the semiconductor chips 2200 may be connected to each other interconnection formed on the interposer substrate.

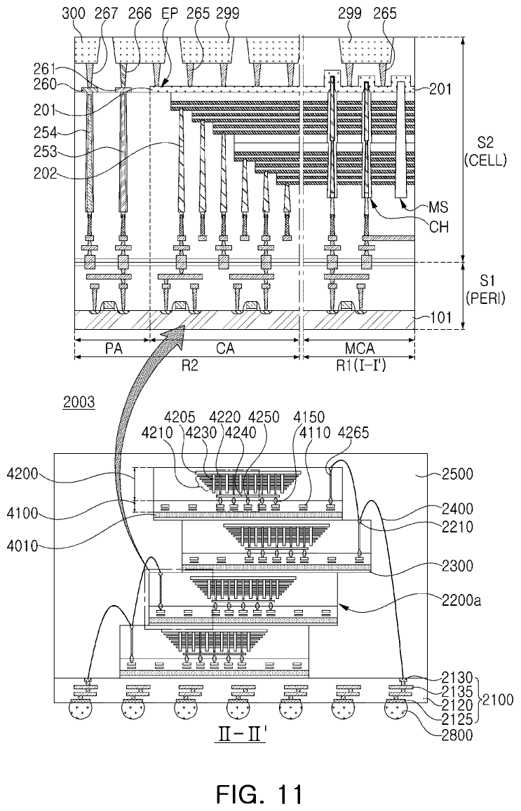

FIG. 11 is a cross-sectional diagram illustrating a semiconductor package according to example embodiments.

FIG. 11 illustrates example embodiments of the semiconductor package 2003 in FIG. 10, illustrating a region of the semiconductor package 2003 taken along line III-III′ in FIG. 10.

Referring to FIG. 11, in the semiconductor package 2003, the package substrate 2100 may be implemented as a printed circuit board. The package substrate 2100 may include a package substrate body 2120, package upper pads 2130 (see FIG. 10) disposed on the upper surface of the package substrate body 2120, lower pads 2125 disposed on the lower surface of the package substrate body 2120 or exposed through the lower surface, and internal interconnections 2135 electrically connecting the package upper pads 2130 to the lower pads 2125 in the package substrate body 2120. The package upper pads 2130 may be electrically connected to the connection structures 2400. The lower pads 2125 may be connected to the interconnection patterns 2005 of the main substrate 2010 of the data storage system 2000 through the conductive connections 2800 as illustrated in FIG. 10.

In the semiconductor package 2003, each of the semiconductor chips 2200a may include a semiconductor substrate 4010, a first semiconductor structure 4100 on the semiconductor substrate 4010, and a second semiconductor structure 4200 bonded to the first semiconductor structure 4100 by a wafer bonding method on the first semiconductor structure 4100.

The first semiconductor structure 4100 may include a peripheral circuit region including a peripheral interconnection 4110 and a lower bonding structure 4150. The second semiconductor structure 4200 may include a common source line 4205, a gate stack structure 4210 disposed between a common source line 4205 and a first semiconductor structure 4100, channel structures 4220 and isolation structure 4230 penetrating through the gate stack structure 4210, and an upper bonding structure 4250 electrically connected to word lines of channel structures 4220 and the gate stack structure 4210. For example, the upper bonding structure 4250 may be electrically connected to the channel structures 4220 and word lines through the gate contact plugs 252 (see FIG. 2c) electrically connected to the bit lines 4240 and word lines electrically connected to channel structures 4220. The lower bonding structure 4150 of the first semiconductor structure 4100 and the upper bonding structure 4250 of the second semiconductor structure 4200 may be bonded to and in contact with each other. Bonded portions of the lower bonding structure 4150 and upper bonding structure 4250 may be formed of, for example, copper (Cu).

As illustrated in the enlarged diagram, the second semiconductor structure 4200 may include via patterns 265 on the second substrate 201, a source contact plug 253 spaced apart from the second substrate 201, a source contact via 266 on the source contact plug 253, and an interconnection line 299 in contact with the upper surface of each of the via patterns 265 on 201, in contact with the upper surface of the source contact via 266 on the external side of the second substrate 201, and electrically connecting the via patterns 265 to the source contact plug 253. In each of the semiconductor chips 2200a, the second substrate 201 may be electrically connected to the interconnection line 299 through the via patterns 265 on the second substrate 201, and the source contact plug 253 may be electrically connected to the interconnection line 299 through the source contact via 266.

Each of the semiconductor chips 2200a may further include an input/output pad 2210 and an input/output connection interconnection 4265 of a lower portion of the input/output pad 2210. The input/output connection interconnection 4265 may be electrically connected to a portion of the lower bonding structure 4150. The input/output pad 2210 may be a region including the conductive pad 300.

The semiconductor chips 2200a in FIG. 11 may be electrically connected to each other by the connection structures 2400 in the form of bonding wires. However, in example embodiments, the semiconductor chips in a semiconductor package, such as the semiconductor chips 2200a in FIG. 11, may be electrically connected to each other by a connection structure including a through-electrode (TSV).

According to the aforementioned example embodiments, by disposing via patterns and interconnection lines on the substrate including a common source line, disposing a source contact via in contact with the interconnection line in an external region of the substrate, and disposing a source contact plug so as to extend vertically from the external side of the substrate and to be connected to the source contact via, a semiconductor device having improved electrical properties and reliability and a data storage system including the same may be provided.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure.

As used herein, an element or region that is “covering” or “surrounding” or “filling” another element or region may completely or partially cover or surround or fill the other element or region. Further, “an element A connected to an element B” (or similar language) may mean that the element A is electrically connected to the element B and/or the element A contacts the element B.

While the example embodiments have been illustrated and described above, it will be configured as apparent to those skilled in the art that modifications and variations could be made without departing from the scope of the present disclosure as defined by the appended claims. Accordingly, the above-disclosed subject matter is to be considered illustrative, and not restrictive, and the appended claims are intended to cover all such modifications, enhancements, and other embodiments, which fall within the scope of the inventive concept. Thus, to the maximum extent allowed by law, the scope is to be determined by the broadest permissible interpretation of the following claims and their equivalents and shall not be restricted or limited by the foregoing detailed description.

What is claimed is:

1. A semiconductor device, comprising:
a first semiconductor structure including a first substrate, circuit devices on the first substrate, a lower interconnection structure electrically connected to the circuit devices, and a lower bonding structure electrically connected to the lower interconnection structure; and
a second semiconductor structure including a second substrate on the first semiconductor structure, gate electrodes stacked and spaced apart from each other in a vertical direction perpendicular to a lower surface of the second substrate, channel structures that penetrate the gate electrodes, extend in the vertical direction, and each of the channel structures includes a respective channel layer, an upper interconnection structure between the gate electrodes and the lower interconnection structure, and an upper bonding structure electrically connected to the upper interconnection structure and bonded to the lower bonding structure,
wherein the second semiconductor structure comprises:
via patterns on the second substrate,
a source contact pad spaced apart from the second substrate in a direction parallel to the lower surface of the second substrate and including a material different from that of the second substrate,
a source contact plug electrically connected to the source contact pad and between the source contact pad and the lower interconnection structure,
a source contact via on the source contact pad, and
an interconnection line in contact with an upper surface of each of the via patterns on the second substrate, in contact with an upper surface of the source contact via, and electrically connecting the via patterns and the source contact plug to each other,
wherein at least a portion of lower surfaces of each of the via patterns is farther from the first substrate than a lower surface of the source contact via, and
wherein at least a portion of an upper surface of the second substrate is farther from the first substrate than an upper surface of the source contact pad.

2. The semiconductor device of claim 1,
wherein the respective channel layers protrudes into the second substrate,
wherein protruding lengths of respective channel layers of different ones of the channel structures are different from one another, and
wherein an upper surface of the second substrate has a protruding portion on the channel layer.

3. The semiconductor device of claim 1, wherein an uppermost end of the channel layer is higher than a an uppermost end of the source contact plug with respect to the first substrate.

4. The semiconductor device of claim 1, wherein the interconnection line includes at least one region having a lattice shape or a line shape on an upper surface of the second substrate.

5. The semiconductor device of claim 1, wherein an upper surface of the source contact plug is lower than an upper surface of the second substrate with respect to the first substrate.

6. The semiconductor device of claim 1, wherein a respective width of an upper portion of respective ones of the via patterns is greater than a respective width of a lower portion thereof.

7. The semiconductor device of claim 1, further comprising:
a conductive plate on the second substrate and including a material different from a material of the second substrate,
wherein each of the via patterns penetrates at least a portion of the conductive plate.

8. The semiconductor device of claim 7, wherein the conductive plate has a protruding portion on an upper surface of the second substrate and is spaced apart from the source contact via, the source contact pad, and the source contact plug.

9. The semiconductor device of claim 1,
wherein the second substrate comprises a semiconductor material, and
wherein each of the via patterns comprises a metal material.

10. The semiconductor device of claim 1, wherein the second semiconductor structure further includes a peripheral contact plug spaced apart from the source contact plug on an external side of the second substrate and extending in the vertical direction.

11. The semiconductor device of claim 10, wherein the second semiconductor structure further includes a peripheral contact pad in contact with an upper surface of the peripheral contact plug and spaced apart from the source contact pad, a peripheral contact via on the peripheral contact pad, and a conductive pad on the peripheral contact via.

12. The semiconductor device of claim 11, wherein the conductive pad is spaced apart from the interconnection line.

13. The semiconductor device of claim 1, wherein the second semiconductor structure further includes gate contact plugs electrically connected to the gate electrodes, respectively, and channel contact plugs electrically connected to the channel structures, respectively.

14. A semiconductor device, further comprising:
a first substrate;
circuit devices on the first substrate;
a lower interconnection structure electrically connected to the circuit devices;
a lower bonding structure electrically connected to the lower interconnection structure;
an upper bonding structure bonded to the lower bonding structure;
an upper interconnection structure electrically connected to the upper bonding structure;
a second substrate on the upper interconnection structure;
gate electrodes between the upper interconnection structure and the second substrate, stacked and spaced apart from each other in a vertical direction perpendicular to a lower surface of the second substrate;
channel structures that penetrate the gate electrodes and each of the channel structures includes a channel layer;
via patterns on the second substrate;
a source contact plug spaced apart from the gate electrodes in a direction parallel to the lower surface of the second substrate on an external side of the second substrate and having an upper surface that is farther from the first substrate than a lower surface of the second substrate;
a source contact via electrically connected to the source contact plug on the source contact plug; and
an interconnection line in contact with an upper surface of each of the via patterns on the second substrate and in contact with an upper surface of the source contact via on an external side of the second substrate,
wherein a lower surface of the source contact via is farther from the first substrate than at least a portion of an upper surface of the second substrate, and
wherein the channel layer protrudes into the second substrate.

15. The semiconductor device of claim 14, further comprising:
a source contact pad in contact with an upper surface of the source contact plug and a lower surface of the source contact via, and including a material different from a material of the second substrate.

16. The semiconductor device of claim 14, further comprising:
a conductive plate on the second substrate and including a material different from a material of the second substrate,
wherein each of the via patterns penetrates at least a portion of the conductive plate.

17. The semiconductor device of claim 14, wherein each of the via patterns is alternately arranged with the channel structures without overlapping the channel structures in the vertical direction.

18. The semiconductor device of claim 14,
wherein each of the via patterns is on respective ones of the channel structures, and
wherein each of the via patterns overlaps the respective ones of the channel structures in the vertical direction.

19. The semiconductor device of claim 14, further comprising:
isolation regions that penetrate the gate electrodes and extend in the vertical direction,
wherein each of the via patterns is on respective ones of the isolation regions and overlap the respective ones of the isolation regions in the vertical direction.

20. A data storage system, comprising:
a semiconductor storage device including a first semiconductor structure including a first substrate with circuit devices on the first substrate; a second semiconductor structure including a second substrate, gate electrodes stacked and spaced apart from each other between the second substrate and the first substrate, and channel structures that penetrate the gate electrodes; and an input/output pad electrically connected to the circuit devices; and
a controller electrically connected to the semiconductor storage device through the input/output pad and configured to control the semiconductor storage device,
wherein the first semiconductor structure includes:
a lower interconnection structure electrically connected to the circuit devices; and
a lower bonding structure electrically connected to the lower interconnection structure,
wherein the second semiconductor structure includes:
an upper bonding structure bonded to the lower bonding structure;
an upper interconnection structure connected to the upper bonding structure;
via patterns on the second substrate;
a source contact pad spaced apart in a direction parallel to a lower surface of the second substrate from the second substrate and including a material different from a material of the second substrate;
a source contact plug electrically connected to the source contact pad, and between the source contact pad and the first substrate;
a source contact via electrically connected to the source contact plug; and
an interconnection line in contact with upper surfaces of the via patterns on the second substrate, in contact with an upper surface of the source contact via on an external side of the second substrate, and electrically connects the via patterns to the source contact plug,
wherein at least a portion of the lower surfaces of each of the via patterns is farther from the first substrate than a lower surface of the source contact via, and
wherein at least a portion of an upper surface of the second substrate is farther from the first substrate than an upper surface of the source contact pad.
